(19) United States
(12) Patent Application Publication
(10) Pub. No.: US 2026/0105972 A1
(43) Pub. Date: Apr. 16, 2026

(54) MEMORY DEVICE AND METHOD OF OPERATING THE SAME

(71) Applicant: Samsung Electronics Co., Ltd., Suwon-si (KR)

(72) Inventors: Woosul Shin, Suwon-si (KR); Yonghyuk Choi, Suwon-si (KR); Hyun Jun Yoon, Suwon-si (KR)

(21) Appl. No.: 19/290,259

(22) Filed: Aug. 4, 2025

(30) Foreign Application Priority Data
Oct. 10, 2024 (KR) 10-2024-0137608

(51) Int. Cl. G11C 16/26; G11C 16/04; G11C 16/10; G11C 16/34

(52) U.S. Cl. CPC G11C 16/26; G11C 16/10; G11C 16/3459; G11C 16/0483

(57) ABSTRACT

The present disclosure relates to a method of operating a memory device including a plurality of memory blocks, each memory block of the plurality of memory blocks including a plurality of pages. An example method includes receiving a read command and an address for controlling a read operation, identifying whether a selected memory block among the plurality of memory blocks is an open block, the selected memory block corresponding to the address, and based on the selected memory block being identified as the open block, controlling a read pass voltage applied to at least one of unselected pages among a plurality of pages included in the selected memory block, the at least one unselected page being different from a selected page corresponding to the address.

### CROSS-REFERENCE TO RELATED APPLICATION

This application claims the benefit of Korean Patent Application No. 10-2024-0137608, filed on Oct. 10, 2024, in the Korean Intellectual Property Office, the disclosure of which is incorporated herein by reference in its entirety.

### BACKGROUND

A memory device includes a plurality of memory blocks, and each of the memory blocks includes a plurality of pages. A page is a unit that stores data according to a program operation or reads data according to a read operation. The memory block may be either an open block or a close block. The open block is a memory block that includes unprogrammed pages, and refers to a memory block that is ready to store additional data. Meanwhile, the close block refers to a memory block in a state where all pages are programmed and program operations can no longer be performed.

In case of a read operation for an open block, excessive current may flow compared to a read operation for a close block. Accordingly, this may result in increased power consumption. Further, for read operations on open blocks, noise may reduce the reliability of data. Accordingly, an efficient solution therefor is desired.

### SUMMARY

The present disclosure relates to a memory device with improved power consumption, and a method of operating the same.

The goals to be achieved by example implementations of the present disclosure are not limited to the technical aspects described above, and other goals may be inferred from the following example implementations.

In some implementations, a method of operating a memory device including a plurality of memory blocks, each memory block of the plurality of memory blocks including a plurality of pages, includes receiving a read command and an address for controlling a read operation, identifying that a selected memory block among the plurality of memory blocks is an open block, the selected memory block corresponding to the address, and based on the selected memory block being identified as the open block, controlling a read pass voltage applied to at least one unselected page of a plurality of unselected pages among a plurality of pages included in the selected memory block, the at least one unselected page being different from a selected page corresponding to the address.

In some implementations, a memory device includes a plurality of memory blocks, each memory block of the plurality of memory blocks including a plurality of pages, and a control logic configured to, based on receiving a read command and an address configured to control a read operation, identify that a selected memory block among the plurality of memory blocks is an open block, the selected memory block corresponding to the address, and based on the selected memory block being identified as the open block, control a read pass voltage applied to at least one unselected page of a plurality of unselected pages among a plurality of pages included in the selected memory block, the at least one unselected page being different from a selected page corresponding to the address.

Specific details of other example implementations are included in the detailed description and drawings.

According to example implementations, it is possible to provide a memory device with improved power consumption and a method of operating the same. According to example implementations, the reliability of the data being read may be improved by using the read operation. According to example implementations, the speed of the read operation may be improved.

Effects of the present disclosure are not limited to those described above, and other effects may be made apparent to those skilled in the art from the following description.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1A is a block diagram illustrating an example of a memory device and an example of a storage device including the same.

FIG. 1B is a drawing for explaining an example of a memory block.

FIG. 2 is a flowchart for explaining an example of an operating method of a memory device.

FIG. 3 is a flowchart for explaining an example of an operating method of a memory device.

FIG. 4 is a drawing for explaining an example of an operation method of a memory device.

FIG. 5A is a drawing for explaining an example of an unprogrammed page.

FIG. 5B is a drawing for explaining an example of a programmed page.

FIG. 6 is a drawing for explaining an example of an open block and an example of a close block.

FIG. 7 is a drawing for explaining example read pass voltages.

FIG. 8 is a drawing for explaining example operation states of a memory device.

FIG. 9 is a drawing for explaining an example of discharge.

FIG. 10 is a flowchart explaining an example of an operation method of a memory device.

FIG. 11 is a drawing for explaining an example of a memory device.

### DETAILED DESCRIPTION

Terms used in the example implementations are selected from currently widely used general terms when possible while considering the functions in the present disclosure. However, the terms may vary depending on the intention or precedent of a person skilled in the art, the emergence of new technology, and the like. Further, in certain cases, there are also terms arbitrarily selected by the applicant, and in the cases, the meaning will be described in detail in the corresponding descriptions. Therefore, the terms used in the present disclosure should be defined based on the meaning of the terms and the contents of the present disclosure, rather than the simple names of the terms.

Throughout the specification, when a part is described as “comprising or including” a component, it does not exclude another component but may further include another component unless otherwise stated. Furthermore, terms such as “ . . . unit,” “ . . . group,” and “ . . . module” described in the specification mean a unit that processes at least one function or operation, which may be implemented as hardware, software, or a combination thereof.

Hereinafter, example implementations of the present disclosure will be described in detail with reference to the accompanying drawings so that those of ordinary skill in the art to which the present disclosure pertains may easily implement them. However, the present disclosure may be implemented in multiple different forms and is not limited to the example implementations described herein.

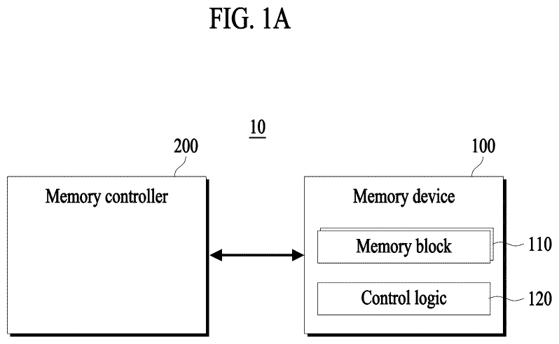

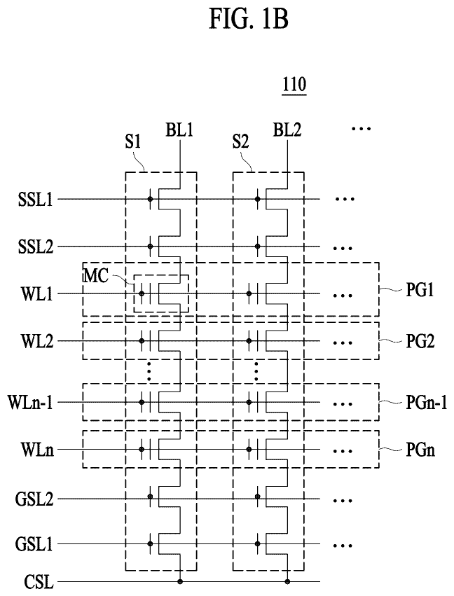

FIG. 1A is a block diagram illustrating an example of a memory device and an example of a storage device including the same.

Referring to FIG. 1A, a storage device 10 may include a memory device 100 and a memory controller 200. In some implementations, the storage device 10 may be implemented as an electronic device in the form of one of a solid state drive (SSD), a USB flash drive, a memory card (e.g., Secure Digital (SD), Secure Digital High Capacity (SDHC), Secure Digital eXtended Capacity (SDXC), Secure Digital Ultra Capacity (SDUC), microSD, microSDHC, microSDXC, microSDUC and so on), network attached storage (NAS), direct attached storage (DAS), and storage area network (SAN). However, the storage device 10 is not limited to the example implementations described above and may be implemented in various modified forms.

The memory device 100 and the memory controller 200 may communicate with each other. For example, the memory device 100 and the memory controller 200 may communicate with each other according to various types of communication standards such as toggle double data rate (DDR), separate command address (SCA) protocol, and open NAND flash interface (ONFI).

The memory device 100 may store data. In some implementations, the memory device 100 may include non-volatile memory configured to retain stored data even when power is cut off.

The memory controller 200 may control the memory device 100. In some implementations, the memory controller 200 may transmit commands to the memory device 100 that control the memory device 100 to perform specific operations. In some implementations, the memory controller 200 may transmit an address to the memory device 100. In some implementations, the memory controller 200 may transmit data to be stored in the memory device 100 to the memory device 100. In some implementations, the memory controller 200 may receive data read from the memory device 100.

The memory device 100 may include at least one memory block 110 and a control logic 120.

The memory block 110 may include a plurality of pages. Each page may include a plurality of memory cells. The memory cell may be a device that stores data. The page is a storage area that serves as a unit of program operation (or write operation) that stores data and a read operation which is reading the data. The memory block 110 may be a storage area that serves as a unit of an erase operation that deletes data.

The control logic 120 may control the overall operation of the memory device 100. When a command and an address are received from the memory controller 200, the control logic 120 may select a specific storage area corresponding to an address and control the selected storage area to perform a specific operation corresponding to a command.

The command may be one of various types such as a program command for controlling the execution of program operations, a read command for controlling the execution of read operations, a suspend command for controlling an operation that is in the process to be suspended, and a resume command for controlling the resumption of the suspended operation.

The address may represent a specific storage area of the memory device 100 or an object on which an operation is to be performed. For example, the address may include at least one of a block address representing a specific memory block among a plurality of memory blocks 110, a row address representing a specific page among a plurality of pages included in a specific memory block, and a column address representing a specific memory cell among a plurality of memory cells included in a single page.

In some implementations, when a program command, an address and data are received, the control logic 120 may perform a program operation on a selected page of a selected memory block corresponding to the address, thereby storing data in the selected page. In some implementations, when a read command and an address are received, the control logic 120 may perform a read operation on a selected page of a selected memory block corresponding to an address and output data stored in the selected page to the memory controller 200.

In some implementations, when a read command and an address are received, the control logic 120 may identify whether a selected memory block corresponding to the address among the plurality of memory blocks 110 is an open block. When the selected memory block is identified as an open block, the control logic 120 may regulate the voltage applied to at least one of a plurality of pages included in the selected memory block.

According to example implementations, provided is the memory device 100 with improved power consumption and a method of operating the memory device 100. Further, the reliability of data that is read by the read operation may be improved. Further, the speed of the read operation may be improved. Hereinafter, example implementations of the present disclosure will be described in more detail with reference to the attached drawings.

FIG. 1B is a drawing for explaining an example of a memory block.

Referring to FIG. 1A and FIG. 1B, the memory block 110 may include a plurality of memory cells MC. In some implementations, the memory cell MC may be a non-volatile memory device that stores data. For example, the memory cell MC may include a control gate, a source, a drain and a charge trap layer (CTL). The control gate may be connected to one of a plurality of word lines (WL1 to WLn). The voltage may be applied to the control gate via the connected word lines. The source and the drain may be terminals through which current flows. The CTL may be an insulating layer that traps charge (e.g., a silicon insulating layer, etc.). The threshold voltage of the memory cell MC may be determined based on the charge stored in the CTL. Meanwhile, the memory cell MC may be implemented by changing the CTL to a floating gate.

The memory block 110 may include a plurality of pages (PG1 to PGn). Each page may be linked to one word line among a plurality of word lines (WL1 to WLn). Each page may include the plurality of memory cells MC connected to the same word line. That is, each control gate of a plurality of memory cells MC included in one page may be connected to one word line.

The memory block 110 may include a plurality of strings (S1, S2 and so on). One end of each string may be connected to one bitline among a plurality of bitlines (BL1, BL2 and so on). The other end of each string may be connected to a common source line (CSL).

Each string may include the plurality of memory cells MC connected in series. Each string may include at least one string select transistor and at least one ground select transistor. The string select transistor and the ground select transistor may be located at either end of the string. That is, a string select transistor may be connected to one end of the plurality of memory cells MC connected in series, and the ground select transistor may be connected to the other end of the series-connected plurality of memory cells MC. The gate of each string select transistor may be connected to a corresponding string selection line (SSL1, SSL2), and a corresponding ground selection line (GSL1, GSL2) may be connected to the gate of each ground select transistor.

For example, when a specific sting (or a memory block) is selected based on an address, the string select transistor and the ground select transistor may be turned on (or activated) depending on the voltage applied to the string selection lines (SSL1, SSL2) and the ground selection lines (GSL1, GSL2). For example, a transistor is turned on (or activated) when the voltage applied to the gate of the transistor is greater than the threshold voltage of the transistor, and current may flow through the channel of the transistor. When the voltage applied to the gate of the transistor is less than the threshold voltage of the transistor, the transistor may be turned off (or disabled), and no current may flow through the transistor.

The control logic 120 may perform program operations to store data in specific areas. The specific areas may be selected based on the address. For example, depending on a block address, a row address, and a column address, the first memory block, the first page and the first memory cell may be selected as areas where data is to be stored.

The program operation may include a program pulse operation and a program verification operation. The program pulse operation may be an operation that increases the threshold voltage of a selected memory cell by injecting charge into the CTL of the selected memory cell. The program verification operation may be an operation to identify whether the threshold voltage of the selected memory cell has reached the target value after the program pulse operation is performed.

For example, the program pulse operation may include applying a program voltage (e.g. 20 V) to the selected page via a word line connected to the selected page, applying a program pass voltage (e.g. 10 V) to a unselected page via a word line connected to the unselected page, applying a program allowance voltage (e.g., 0 V) to the bitline connected to the memory cell to be programmed and applying a program inhibit voltage (e.g., 10 V) to a bitline connected to a memory cell that is not to be programmed.

For example, the program verification operation may include applying a program verification voltage (e.g. 2 V, 3 V, 5 V, etc.) to the selected page via a word line connected to the selected page, applying a verification pass voltage (e.g. 10 V) to a unselected page via a word line connected to the unselected page, and identifying whether the program is complete based on the current flow of the bitline connected to the memory cell to be programmed.

In some implementations, when it is identified that the program is completed according to the program verification operation, the control logic 120 may terminate the program operation, and when it is identified that the program is not completed according to the program verification operation, the control logic 120 may perform the following program operations. As such, program operations may be repeated based on a result of the program verification operation. Meanwhile, the control logic 120 may increase the level of the program voltage applied in the program pulse operation of the next program operation.

The control logic 120 may perform a read operation to output data stored in a specific area. The specific area may be selected based on the address. For example, depending on the block address, the row address and the column address, the first memory block, the first page and the first memory cell may be selected as the area where data is stored.

For example, the read operation may include applying a read voltage (e.g. 2V, 3V, 5V, etc.) to the selected page through a word line connected to the selected page, applying a read pass voltage (e.g. 10 V) to a unselected page through a word line connected to the unselected page, and reading data by identifying the current flowing through the bitline according to the threshold voltage and the read voltage of the memory cell corresponding to the stored data.

When a read command and an address are received, the control logic 120 may identify whether the selected memory block corresponding to the address is an open block. Here, the selected memory block may be selected from the plurality of memory blocks 110 based on the address (e.g., a block address).

The open block may be a memory block including unprogrammed pages. In some implementations, an open block may further include programmed pages. Meanwhile, a close block may be a memory block where all pages are programmed pages. That is, a close block may be a memory block that includes only programmed pages. The programmed page may be a page where program operations are performed and data is stored. The unprogrammed page may be a page that is in an initialized state because no program operation has been performed yet. When a program operation is performed on an unprogrammed page, the unprogrammed page may change its state to a programmed page. That is, the memory block 110 may be classified as an open block or a close block depending on the state of a plurality of pages (PG1 to PGn).

When the selected memory block is identified as an open block, the control logic 120 may perform a read operation by controlling the voltage applied to at least one of a plurality of pages included in a selected memory block.

In some implementations, the control logic 120 may control the read voltage applied to a selected page of a selected memory block. Here, the selected page may be a page that is selected according to an address (for example, a row address). In some implementations, the control logic 120 may control a read pass voltage applied to at least one of the unselected pages of the selected memory block. Here, the unselected page may be a page different from the selected page within the same memory block. For example, when the first page PG1 is the selected page among the plurality of pages (PG1 to PGn) included in the memory block 110, a second page PG2 to an nth page PGn may be unselected pages.

In some implementations, the memory device 100 may further include a register. In some implementations, the register may be located within the control logic 120, or may be located separately outside the control logic 120. In some implementations, the register may be implemented as a flip-flop, but is not limited thereto. The register may be implemented in various forms, such as a latch, volatile memory and non-volatile memory.

In some implementations, a register may store page information for the last programmed page of a selected memory block. The page information may include a block address indicating the selected memory block and a row address indicating the last programmed page. In other words, the page information may be information about one memory block. In some implementations, the register may store the page information for the last programmed page for each of the plurality of memory blocks 110. For example, the page information may include a block address representing each memory block and a row address indicating the last programmed page of each memory block. In other words, the page information may be information about a plurality of memory blocks.

In some implementations, a register may store the address of a program operation that was performed immediately before. The address may include a block address indicating a memory block where a program operation was performed immediately before.

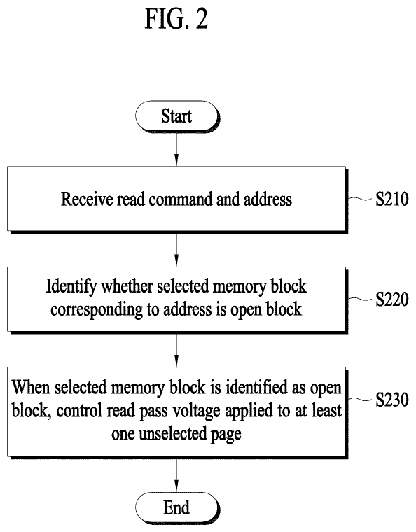

FIG. 2 is a flowchart for explaining an example of an operating method of a memory device.

Referring to FIG. 2, a method for operating the memory device 100 according to some implementations may include operation S210 that is receiving a read command and an address for controlling a read operation. For example, the read command and the address may be received from the memory controller 200. The address may include a block address indicating a selected memory block and a row address indicating a selected page. In some implementations, the address may further include a column address representing a selection string.

The method for operating the memory device 100 may include operation S220 that is identifying whether a selected memory block corresponding to an address among the plurality of memory blocks 110 is an open block.

For example, an open block could be a memory block including unprogrammed pages. In some implementations, an open block may further include programmed pages. In some implementations, when the selected memory block is not the open block, the selected memory block may be a close block. The close block may be a memory block where all pages are programmed pages.

When the selected memory block is identified as an open block, the method for operating the memory device 100 may include operation S230 that is controlling a read pass voltage applied to at least one unselected page different from the selected page corresponding to the address among a plurality of pages included in the selected memory block.

In some implementations, the method for operating the memory device 100 may further include performing a read operation. The read operation may be applying read pass voltage to an unselected page of a selected memory block, and applying the read voltage to the selected page of the selected memory block. In some implementations, in the case of the read operation of the selected memory block what is identified as an open block, the method for operating the memory device 100 may include applying the first read pass voltage to the programmed page among the unselected pages of the selected memory block, and applying the second read pass voltage to an unprogrammed page among the unselected pages of the selected memory block.

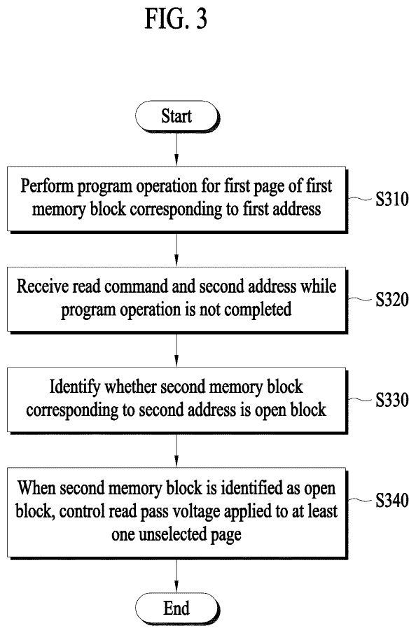

FIG. 3 is a flowchart for explaining an example of an operating method of a memory device.

Referring to FIG. 3, the method for operating the memory device 100 may include operation S310 that is performing a program operation for a first page of a first memory block corresponding to a first address among the plurality of memory blocks 110 included in the memory device 100.

A first address may be received from the memory controller 200. The first address may include a first block address indicating the first memory block and a first row address indicating the first page. In some implementations, the first address may further include a first column address indicating a first string (or a first bitline).

In some implementations, the program operation may include a program pulse operation and a program verification operation. The program pulse operation may include applying program voltage to the first page of the first memory block, and applying a program pass voltage to an unselected page other than the first page among a plurality of pages included in the first memory block. The program verification operation may include applying the program verification voltage to the first page of the first memory block, and applying the verification pass voltage to an unselected page of the first memory block. As a result of the program verification operation, when it is identified that the threshold value does not reach the target value, the program operation may be repeated.

In some implementations, the method for operating the memory device 100 may further include storing a first address. For example, the first address may be stored in a register included in the memory device 100.

The method for operating the memory device 100 may further include operation S320 that is receiving a read command and a second address to control the read operation while the program operation is not completed.

The read command and a second address may be received from the memory controller 200. The second address may include a second block address, which represents a second memory block (or an optional memory block) and a second row address indicating the second page (or a selected page). In some implementations, the second address may further include a second column address indicating a second string (or a second bitline).

The state in which a program operation is incomplete may be either a state in which the program operation is suspended or a state in which the program operation is being performed. For example, the read command may be received while a suspend command is received and the program operation is suspended. In other words, the read command may be received after the suspend command is received. In some implementations, the read command may be received while a program operation is being performed.

In some implementations, operation S320 of receiving a read command and a second address may include receiving a suspend command while the program operation is in progress, suspending the program operation according to the suspend command, and receiving the read command and the second address while the program operation is suspended.

In some implementations, operation S320 of receiving a read command and a second address may include receiving a read command and a second address while a program operation is in progress, and suspending the program operation according to the read command.

The method for operating the memory device 100 may include operation S330 that is identifying whether the second memory block corresponding to the second address among the plurality of memory blocks 110 is an open block.

In some implementations, the first memory block where the program operation is not completed may be an open block. For example, the second memory block may be the same memory block as the first memory block. In this case, the second memory block may be an open block. In some implementations, the second memory block may be a memory block different from the first memory block. In this case, the second memory block may be an open block or a close block.

In some implementations, operation S330 that is identifying whether the second memory block is an open block may include identifying whether the first memory block and the second memory block are the same by comparing the first address and the second address, and when the first memory block and the second memory block are identical, identifying the second memory block as an open block. For example, when the second block address of the second address is the same as the first block address of the first address, the second memory block may be identified as an open block. Further, in this case, the second memory block may be identified as the memory block where the program operation was performed immediately before.

When the second memory block is identified as an open block, the method for operating the memory device 100 may include operation S340 that is controlling a read pass voltage applied to at least one unselected page other than the second page corresponding to the second address among a plurality of pages included in a second memory block.

The second memory block is a selected memory block, and the second page may be a selected page. The read pass voltage may be the voltage applied to an unselected page through a word line connected to the unselected page during a read operation.

In some implementations, the method for operating the memory device 100 may further include performing the read operation. The read operation may include applying the first read pass voltage to the programmed page of the unselected page of the second memory block identified as an open block, applying the second read pass voltage to the unprogrammed page of the unselected page of the second memory block, and applying the read voltage to the second page of the second memory block.

In some implementations, in the read operation, when the first memory block and the second memory block are the same, the read operation may be performed by applying a first read pass voltage, a second read pass voltage, and a read voltage without discharging the voltage applied during the program operation.

In some implementations, operation S340 of controlling a read pass voltage may include controlling a second target level of the second read pass voltage to be smaller than a first target level of the first read pass voltage. In some implementations, controlling the read pass voltage may include controlling the slope in which a level of the second read pass voltage increases to be smaller than the slope in which a level of the first read pass voltage increases. In some implementations, controlling the read pass voltage may include controlling time that is taken for the level of the second read pass voltage to reach the second target level to be less than time that is taken for the level of the first read pass voltage to reach the first target level.

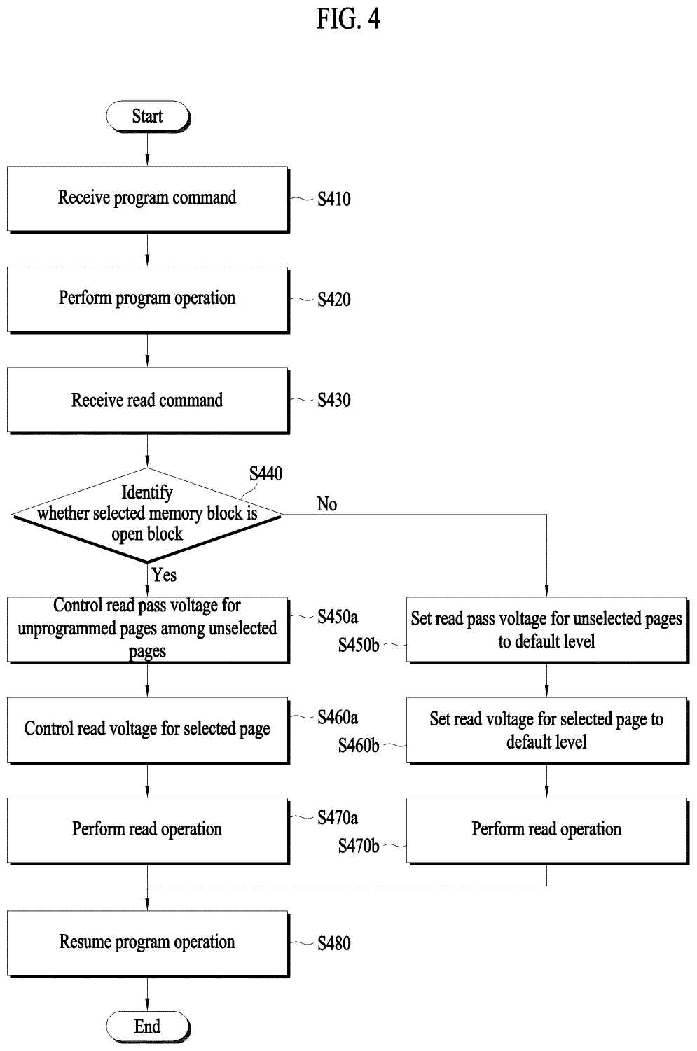

FIG. 4 is a drawing for explaining an example of an operation method of a memory device.

Referring to FIG. 4, the method for operating the memory device 100 may include operation S410 that is receiving a program command. The program command may be received from the memory controller 200 along with the first address. In the method for operating the memory device 100, depending on the first address, a specific memory block may be selected as the target of a program operation. In some implementations, the method for operating the memory device 100 may include storing the first address.

The method for operating the memory device 100 may include operation S420 that is performing a program operation. For example, the method for operating the memory device 100 may include performing a program operation on a memory block corresponding to an address according to a program command.

The method for operating the memory device 100 may include operation S430 that is receiving a read command. The read command may be received from the memory controller 200 with a second address. The second address may be the same as or different from the first address. In the method for operating the memory device 100, depending on the second address, a specific memory block may be selected as the target of the read operation. Hereinafter, the memory block corresponding to the second address is referred to as the selected memory block.

The method for operating the memory device 100 may include operation S440 that is identifying whether the selected memory block is an open block.

In some implementations, the first address may be pre-stored in a register of the memory device 100. In this case, in the method for operating the memory device 100, by comparing the stored first address and the received second address, whether the selected memory block is an open block may be identified.

In some implementations, the page information for the most recently programmed page for the selected memory block may be pre-stored in the registers of the memory device 100. In this case, in the method for operating the memory device 100, by comparing the number of the last programmed page of the selected memory block with the number of the last page of the selected memory block based on the page information, whether the selected memory block is an open block may be identified.

In some implementations, open block information indicating whether a selected memory block is an open block may be stored in advance in a register of the memory device 100. In this case, in the method for operating the memory device 100, whether the selected memory block is an open block based on open block information may be identified.

Below, example implementations are described based on the case where the selected memory block is identified as an open block (S440, Yes). Meanwhile, the order of operation S450a and operation S460a may be changed, or operation S450a and operation S460a performed simultaneously. In some implementations, one of operation S450a and operation S460a may be omitted.

In some implementations, the method for operating the memory device 100 may include operation S450a that is controlling the read pass voltage for unprogrammed pages among the unselected pages of the selected memory block.

In some implementations, the target level of the read pass voltage for an unprogrammed page may be controlled to be smaller than the target level of the read pass voltage for a programmed page.

In some implementations, the slope in which the level of the read pass voltage for unprogrammed pages increases may be controlled to be smaller than the slope in which the level of the read pass voltage for the programed page increases.

In some implementations, time that is taken for a level of the read pass voltage for an unprogrammed page to reach the target level may be controlled to be smaller than time that is taken for a level of the read pass voltage for the programmed page to reach the target level.

The method for operating the memory device 100 may include operation S460a that is controlling the read voltage for a selected page of the selected memory block.

In some implementations, a target level of the read voltage applied to the selected page of the selected memory block may be controlled more significantly than a target level of the read voltage applied to the selected page of the close block.

The method for operating the memory device 100 may include operation S470a that is performing a read operation. The read operation may include applying the first read pass voltage to the programmed page of the unselected page of the selected memory block identified as an open block, applying a second read pass voltage to an unprogrammed page of an unselected page of a selected memory block, and applying the read voltage to the selected page of the selected memory block. Here, the second read pass voltage and/or the read voltage may be controlled according to the operation described above.

Meanwhile, example implementations are described below based on that the selected memory block is identified as no open block (S440, No). In this case, the selected memory block may be a close block. Meanwhile, the order of operation S450b and operation S460b may be changed, or operation S450b and operation S460b performed simultaneously.

The method for operating the memory device 100 may include operation S450b that is setting the read pass voltage for unselected pages of the selected memory block to the default level. Here, the default level indicates the target level of the read pass voltage and may have a preset value.

The method for operating the memory device 100 may include operation S460b that is setting the read voltage for the selected page of the selected memory block to the default level. Here, the default level indicates the target level of the read voltage and may have a preset value.

The method for operating the memory device 100 may include operation S470b that is performing a read operation. The read operation may include applying the read pass voltage to unselected pages of a selected memory block identified as a close block, and applying the read voltage to the selected page of the selected memory block.

In some implementations, after performing operation S420 which is performing the program operation, when the read operation is performed while the program operation is incomplete (operation S470a, operation S470b), the method for operating the memory device 100 may include operation S480 that is resuming the program operation. For example, when the read operation is complete, the method for operating the memory device 100 may include resuming the suspended operation during the program pulse operation or the program verification operation. Meanwhile, after operation S420 which is performing the program operation, when the read operation is performed while the program operation is completed (operation S470a, operation S470b), operation S480 which is resuming the program operation may be omitted.

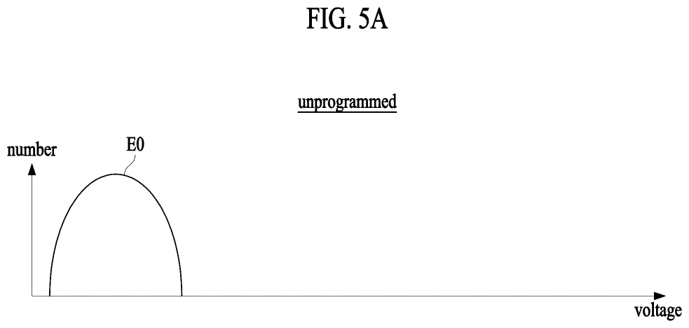

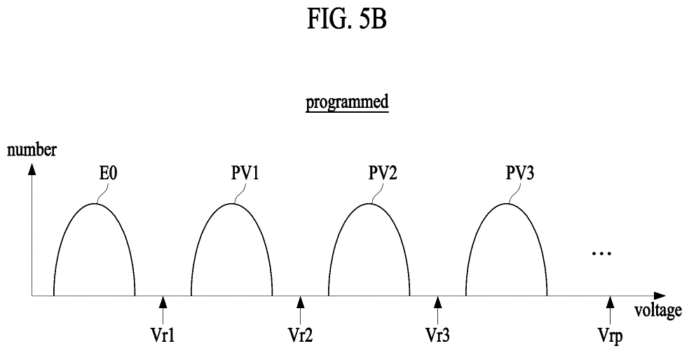

FIG. 5A is a drawing for explaining an example of an unprogrammed page. FIG. 5B is a drawing for explaining an example of a programmed page.

Referring to FIG. 5A and FIG. 5B, the horizontal axis of the graphs represents voltage, and the vertical axis of the graphs represents the number of memory cells with that threshold voltage within the page.

A memory cell included in an unprogrammed page may be in a 0th threshold voltage state E0. The 0th threshold voltage state E0 may be a state corresponding to the threshold voltage of a memory cell in which a program operation has not been performed after an erase operation has been performed. The 0th threshold voltage state E0 may be referred to as the erase state or the initial state.

When a program operation is performed on an unprogrammed page, the unprogrammed page may change its state to a programmed page. In some implementations, the threshold voltage distribution of a memory cell may be changed from FIG. 5A to FIG. 5B. For example, among the memory cells of erase state (E0) included in the unprogrammed page, some may maintain the erase state (E0), some others may be changed to a first threshold voltage state PV1, some others may be changed to a second threshold voltage state PV2, and some others may be changed to a third threshold voltage state PV3. In other words, a threshold voltage of at least some of the plurality of memory cells included in an unprogrammed page may be changed. The first threshold voltage state to the third threshold voltage state (PV1 to PV3) may be referred to as the program state.

Each memory cell may belong to one of a plurality of threshold voltage states (E0, and PV1 to PV3) depending on the threshold voltage. Each of the threshold voltage states (E0, and PV1 to PV3) represents data, and may be identified by a read voltage (Vr1 to Vr3). The threshold voltage states (E0, and PV1 to PV3) and the read voltages (Vr1 to Vr3) may be set depending on the data storage method.

For example, in the case of multi-level cell (MLC) that stores 2 bits in one memory cell, there may be four voltage ranges. In this case, if the threshold voltage of the memory cell falls within the first voltage range, the data stored in the memory cell may be interpreted as “11,” and when the threshold voltage of the memory cell falls within the second voltage range, which is higher than the first voltage range, the data stored in the memory cell may be interpreted as “10.” Further, when the threshold voltage of the memory cell falls within the third voltage range, which is higher than the second voltage range, data stored in the memory cell may be interpreted as “00” and when the threshold voltage of the memory cell falls within the fourth voltage range, which is higher than the third voltage range, the data stored in the memory cell may be interpreted as “01.” However, it is a mere example implementation, and values of the data may be implemented in various ways. In this case, when the three read voltages (Vr1 to Vr3) applied to the page during the read operation are greater than the threshold voltage, the state of each memory cell within a page may be identified by identifying the current flowing through each bitline.

Meanwhile, in a similar manner, memory cells may be implemented in various variations, such as a single level cell (SLC) that stores 1 bit, a triple-level cell (TLC) that stores 3 bits, and a quad-level cell (QLC) that stores 4 bits.

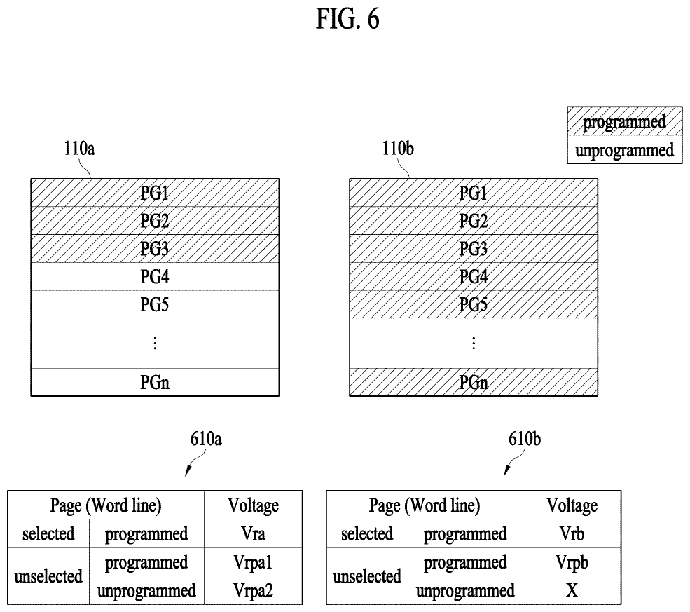

FIG. 6 is a drawing for explaining an example of an open block and an example of a close block.

Referring to FIG. 6, each of the memory blocks 110a and 110b may be an open block or a close block. The open block may include unprogrammed pages. In some implementations, an open block may further include programmed pages. Meanwhile, a close block may include only programmed pages.

For example, the first memory block 110a may include a plurality of pages (PG1 to PGn), and the 4th to nth pages (PG4 to PGn) among the plurality of pages (PG1 to PGn) may be unprogrammed pages. In this case, the first memory block 110a may be an open block. The second memory block 110b may include a plurality of pages (PG1 to PGn), and the plurality of pages (PG1 to PGn) may all be programmed pages. In this case, the second memory block 110b is a close block.

In some implementations, the control logic 120 of the memory device 100 may sequentially perform program operations on a plurality of pages (PG1 to PGn) within a memory block (the first memory block 110a, and the second memory block 110b). For example, the program operations may be performed sequentially from the first page PG1 to the nth page PGn. In some implementations, program operations may be performed sequentially from the nth page PGn to the first page PG1. Below, example implementations are described based on that program operations are performed in the order of a first page PG1 to the nth page PGn.

In some implementations, the control logic 120 may identify from the next page of the last programmed page among the plurality of pages (PG1 to PGn) included in the memory block (the first memory block 110a, and the second memory block 110b) as an unprogrammed page according to the page information for the last programmed page. In some implementations, the page information may be stored in a register.

For example, a third page PG3 of the first memory block 110a may be the page on which the program operation was performed most recently. In this case, the control logic 120 may identify the nth page PGn from a fourth page PG4, which is the next page of the third page PG3, as unprogrammed pages according to page information. Further, the control logic 120 may identify the first memory block 110a as an open block according to the page information.

In some implementations, the nth page PGn of the second memory block 110b may be the page on which the program operation was most recently performed. In this case, the control logic 120 may identify that the next page of the nth page PGn does not exist based on the page information. Further, the control logic 120 may identify the second memory block 110b as a close block according to page information.

Below, example implementations are described based on the voltage that is applied during a read operation for the first memory block 110a, which is an open block. With respect thereto, example implementations are described based on that the second page PG2 among the plurality of pages (PG1 to PGn) included in the first memory block 110a is selected as the target of the read operation.

In this case, the selected page is the first page PG1, and the unselected page may be the second page PG2 to the nth page PGn. Among the unselected pages, the unprogrammed page may be the 4th to nth page (PG4 to PGn), and among the unselected pages, the programmed pages may be the second page PG2 to the third page PG3. Meanwhile, pages where program operations are suspended may be treated like programmed pages. During a read operation, a first read voltage Vra may be applied to the first page PG1, a first read pass voltage Vrpa1 may be applied to the second page PG2 to the third page PG3, and a second read pass voltage Vrpa2 may be applied to the second page PG2 to the third page PG3.

Below, example implementations are described based on the voltage that is applied during a read operation for the second memory block 110b, which is a close block. Example implementations are described based on that, among the plurality of pages (PG1 to PGn) included in the second memory block 110b, the first page PG1 is selected as the target of the read operation.

In this case, the selected page may be the first page PG1, and the unselected page may be the second page PG2 to the nth page PGn. Among the unselected pages, the programmed page may be the second page PG2 to the nth page PGn. During a read operation, a second read voltage Vrb may be applied to the first page PG1, and a third read pass voltage Vrpb may be applied from the second page PG2 to the nth page PGn.

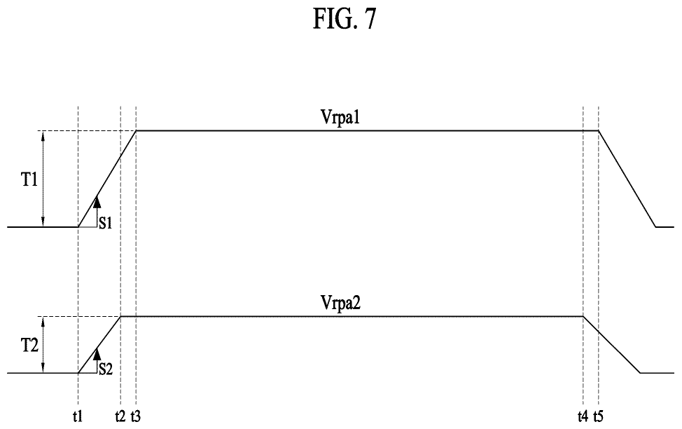

FIG. 7 is a drawing for explaining example read pass voltages.

Referring to FIG. 6 and FIG. 7, the control logic 120 of the memory device 100 according to the implementation may control a second target level T2 of the second read pass voltage Vrpa2 applied to the unprogrammed page among the unselected pages of the selected memory block to be smaller than a first target level T1 of the first read pass voltage Vrpa1 applied to the programmed page among the unselected pages of the selected memory block, which is an open block.

The first target level T1 and the second target level T2 may be the maximum levels of the voltage applied to the page. For example, when the first target level T1 of the first read pass voltage Vrpa1 is 6V, the control logic 120 may control the second target level T2 of the second read pass voltage Vrpa2 to one of values, such as 3 V, 4 V and 5 V. The first target level T1 and the second target level T2 may be set to a value greater than the threshold voltage of a plurality of memory cells included in the unselected page. This is to turn on all memory cells included in the unselected page to which the read pass voltage is applied. In the case of the memory cells included in unprogrammed pages among unselected pages, all are in the erase state and have relatively low threshold voltages, but memory cells included in programmed pages may have relatively high threshold voltages in the program state. In other words, even if the second target level T2 of the second read pass voltage Vrpa2 applied to the unprogrammed page is controlled lower than the first target level T1, all memory cells included in the unprogrammed page to which the second read pass voltage Vrpa2 is applied may be turned on. Accordingly, the power consumed during a read operation of the memory device 100 may be reduced.

In some implementations, the control logic 120 may control a second slope S2 in which a level of the second read pass voltage Vrpa2 increases to be smaller than a first slope S1 in which a level of the first read pass voltage Vrpa1 increases.

The first slope S1 may be the slope between a first timepoint t1 at which a level of the first read pass voltage Vrpa1 starts to rise and a third timepoint t3 at which a level of the first read pass voltage Vrpa1 reaches the first target level T1. The second slope S2 may be the slope between the first timepoint t1 at which the level of the second read pass voltage Vrpa2 increases and a second timepoint t2 at which the level of the second read pass voltage Vrpa2 reaches the second target level T2.

In some implementations, the control logic 120 may include controlling the second time that the level of the second read pass voltage Vrpa2 reaches the second target level T2 to be smaller than the first time that the level of the first read pass voltage Vrpa1 reaches the first target level T1.

For example, the first time point may be the time between the first timepoint t1 at which a level of the first read pass voltage Vrpa1 starts to rise and the third timepoint t3 at which a level of the first read pass voltage Vrpa1 reaches the first target level T1. The second time may be the time between the first timepoint t1 at which a level of the second read pass voltage Vrpa2 starts to increase and the second timepoint t2 at which the level of the second read pass voltage Vrpa2 reaches the second target level T2. In some implementations, a fourth timepoint t4 at which the second read pass voltage Vrpa2 is discharged may be earlier than a fifth timepoint t5 at which the first read pass voltage Vrpa1 is discharged. This is because the second read pass voltage Vrpa2 may reach the target level faster than the first read pass voltage Vrpa1.

In some implementations, the control logic 120 may control the second target level T2 of the second read pass voltage Vrpa2 applied to the unprogrammed page among the unselected pages of the selected memory block, which is an open block, to be smaller than the third target level of the third read pass voltage Vrpb that is set to be applied to the unselected page of the close block during a read operation on the close block. In some implementations, the third target level may be the same as or different from the first target level T1. The third target level may be the default level.

In some implementations, the control logic 120 may control the target level of the first read voltage Vra applied to the selected page of the selected memory block, which is an open block, to be greater than the target level of the second read voltage Vrb that is set to be applied to the selected page of the close block during a read operation on the close block. The target level may be the maximum level of voltage applied to the word line. The target level of the second read voltage Vrb may be a preset default level. The target level of the first read voltage Vra may be controlled to a value greater than the default level.

For example, when the number of memory cells in the erase state is greater than the plurality of memory cells included in the memory block, the source voltage may increase. In this case, the gate-source voltage, which is the difference between the gate voltage of the memory cell (e.g., the voltage applied to the control gate) and the source voltage, may be lowered so that the gate-source voltage becomes less than the threshold voltage, and thus the reliability of the read data may be reduced. Accordingly, for open blocks, the target level of the first read voltage Vra may be controlled to a larger value, and the gate-source voltage is precisely compensated and the reliability of data may be improved.

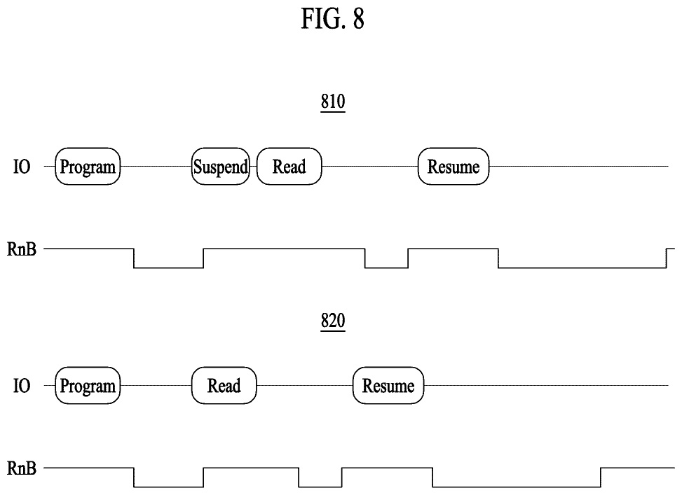

FIG. 8 is a drawing for explaining example operation states of a memory device.

Referring to FIG. 8, the memory device 100 may include a communication interface for communicating with the memory controller 200. The communication interface may include an input/output pin IO and a ready/busy pin Rnb.

The memory device 100 may receive commands from the memory controller 200 through the input/output pin IO. The commands may include various types of commands, such as a program command, a suspend command, a read command and a resume command. In some implementations, the memory device 100 may receive an address from the memory controller 200 via the input/output pin IO.

The memory device 100 may output state information of the memory device 100 to the memory controller 200 through the ready/busy pin Rnb. The state information may indicate a READY state where the memory device 100 is waiting or a BUSY state where the memory device 100 is operating. For example, “high” in the state information may indicate a READY state, and “low” in the operation state information may indicate a BUSY state. However, it is a mere example implementation, and it may be implemented in a transformed example implementation in the opposite direction. Hereinafter, example implementations are described based on that “high” in the state information indicates the READY state, and “low” in the operation state information indicates the BUSY state.

In some implementations, when a program command and a block address are received, the control logic 120 of the memory device 100 may perform a program operation on a memory block corresponding to a block address among the plurality of memory blocks 110. In other words, when a program command is received before a read command is received, the program operation may be performed first.

In some implementations, when a suspend command or a read command is received while a program operation is being performed, the control logic 120 may suspend the program operation. For example, when a suspend command is received while a program operation is being performed, the control logic 120 may suspend the program operation. In some implementations, when a read command and an address are received while a program operation is being performed, the control logic 120 may suspend the program operation.

In some implementations, when the memory block corresponding to the block address and the selected memory block corresponding to the address are the same, the control logic 120 may identify the selected memory block as an open block. The control logic 120 may perform a read operation by controlling the voltage applied to at least one of a plurality of pages included in a selected memory block identified as an open block. In some implementations, when the read operation for the selected page of the selected memory block is completed, the control logic 120 may resume the program operation for the selected memory block.

Specifically, referring to a first timing diagram 810 of FIG. 8, when receiving a program command and an address, the memory device 100 may perform a program operation. While the memory device 100 performs a program operation, the state information of the memory device 100 may be “low.”

While performing a program operation, the memory device 100 may receive a suspend command. The memory device 100 may suspend the program operation by a suspend command. When the program operation is suspended, the state information of the memory device 100 may be changed to “high” and maintained.

After then, the memory device 100 may receive a read command and an address. The memory device 100 may identify whether the selected memory block corresponding to the address is an open block. When the selected memory block is an open block, the memory device 100 may perform a read operation by controlling the read voltage or the read pass voltage. Unlike this, when the selected memory block is a close block, the memory device 100 may perform a read operation by setting it to the default level without controlling the read voltage and the read pass voltage. Meanwhile, while the memory device 100 performing the read operation, the state information of the memory device 100 may be “low.”

After then, when the read operation of the memory device 100 is completed, the state information of the memory device 100 may be changed to “high.” After then, the memory device 100 may receive the resume command. In this case, the memory device 100 may resume the suspended program operation. In some implementations, when the read operation is completed without a resume command, the memory device 100 may resume the suspended program operation.

Meanwhile, referring to a second timing diagram 820 of FIG. 8, when receiving a program command and an address, the memory device 100 may perform a program operation. While the memory device 100 is performing the program operation, the state information of the memory device 100 may be “low.”

While performing the program operation, the memory device 100 may receive the read command and the address without a suspend command. The memory device 100 may suspend the program operation upon the read command. Here, the read command may also perform a trigger function that suspends the program operation. When the program operation is suspended, the state information of the memory device 100 may be changed to “high” and maintained.

The memory device 100 may identify whether the selected memory block corresponding to the address is an open block. When the selected memory block is an open block, the memory device 100 may perform the read operation by controlling the read voltage or the read pass voltage. Unlike this, when the selected memory block is a close block, the memory device 100 may perform a read operation by setting it to the default level without controlling the read voltage and the read pass voltage. Meanwhile, while the memory device 100 performs a read operation, the state information of the memory device 100 may be “low.” After then, when the read operation of the memory device 100 is completed, the state information of the memory device 100 may be changed to “high.”

After then, the memory device 100 may receive the resume command. In this case, the memory device 100 may resume the suspended program operation. In some implementations, when the read operation is completed without a resume command, the memory device 100 may resume the suspended program operation.

According to example implementations of the present disclosure, the memory device 100 may perform the suspend operation and the read operation of the previous program operation using the read command, and thus the completion time of the operation may be reduced.

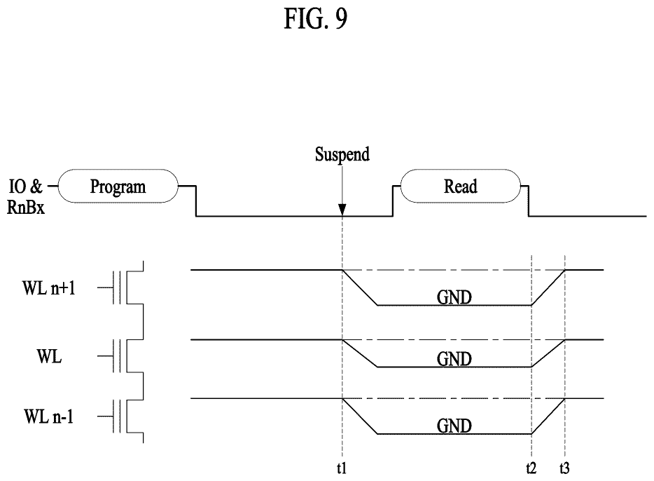

FIG. 9 is a drawing for explaining an example of discharge. FIG. 9 illustrates a timing diagram for the voltage applied to some pages of a memory block and the command and state information.

Referring to FIG. 9, the control logic 120 of the memory device 100 may perform a program operation on a memory block corresponding to an address according to the received program command and the received address. During the program operation, the voltage (e.g. program voltage, program pass voltage, program verification voltage, verification pass voltage, etc.) may be applied through word lines (WLn1 to WL3) connected to pages included in the memory block.

In some implementations, while performing a program operation on a specific memory block, the control logic 120 may discharge the voltage applied to each page of the memory block when a suspend command (or a read command) is received. For example, the voltage may be discharged until a level of the voltage to be a ground level GND. In other words, during discharging the voltage, the voltage level may be gradually reduced until the level reaches the ground level GND.

After then, while performing the read operation on the same memory block, the control logic 120 may apply the read voltage to a selected page of the memory block, and apply a read pass voltage to an unselected page of the memory block. In this case, the levels of the read voltage and the read pass voltage may rise from the ground level GND to their respective target levels.

In some implementations, when a read command and an address are received, the control logic 120 may identify whether the memory block on which the previous program operation was performed and the selected memory block on which the read operation is to be performed are the same. For example, the control logic 120 may store the block address received along with the program command, and compare the block address received with the read command with the stored block address to identify whether the memory blocks are identical.

When it is identified that the memory block and the selected memory block are the same, the control logic 120 may apply the read voltage and the read pass voltage to selected and unselected pages of a selected memory block without discharging the voltage applied during the program operation. In other words, the voltage level dropping to the ground level GND may be omitted due to discharge, and the level of the applied voltage may be maintained during the program operation.

After then, while performing the read operation on the same memory block, the control logic 120 may apply the read voltage to the selected page of the memory block, and apply the read pass voltage to an unselected page of the memory block. In this case, a level of each of the read voltage and the read pass voltage may be changed from the level of the voltage applied during the program operation to the respective target level. Accordingly, the completion time of an operation performed by the memory device 100 may be reduced.

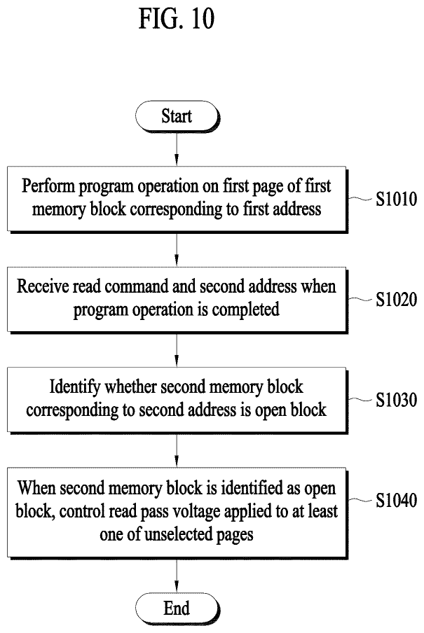

FIG. 10 is a flowchart explaining an example of an operation method of a memory device.

Referring to FIG. 10, the method for operating the memory device 100 may include operation S1010 that is performing a program operation on the first page of the first memory block corresponding to the first address among the plurality of memory blocks 110.

The method for operating the memory device 100 may include operation S1020 that is receiving a read command and a second address to control the read operation when the program operation is completed.

The method for operating the memory device 100 may include operation S1030 that is identifying whether the second memory block corresponding to the second address among the plurality of memory blocks 110 is an open block.

For example, the second memory block may be the same memory block as the first memory block. In this case, the second memory block may be an open block. In some implementations, the second memory block may be a memory block different from the first memory block. In this case, the second memory block may be an open block or a close block.

The method for operating the memory device 100 may include operation S1040 in which, when the second memory block is identified as an open block, the read pass voltage applied to at least one of unselected pages other than the second page corresponding to the second address among the plurality of pages included in the second memory block is controlled.

In some implementations, method for operating the memory device 100 may further include performing the read operation. The read operation may include applying the first read pass voltage to the programmed page of the unselected page of the second memory block identified as an open block, applying the second read pass voltage to the unprogrammed page of the unselected page of the second memory block, and applying the read voltage to the second page of the second memory block.

In some implementations, in performing the read operation, when the first memory block and the second memory block are the same, the read operation may be performed by applying a first read pass voltage, a second read pass voltage and a read voltage without discharging the voltage applied during the program operation.

In some implementations, operation S1040 that is controlling the read pass voltage may include controlling the second target level of the second read pass voltage to be smaller than the first target level of the first read pass voltage. In some implementations, controlling the read pass voltage may include controlling the slope in which the level of the second rad pass voltage increases to be smaller than the slope in which the level of the first read pass voltage increases. In some implementations, controlling the read pass voltage may include controlling the time taken for the level of the second read pass voltage to reach the second target level to be smaller than the time taken for the level of the first read pass voltage to reach the first target level.

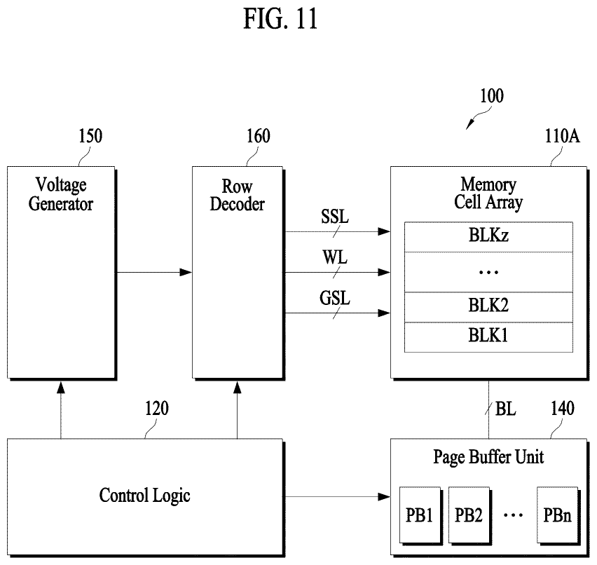

FIG. 11 is a drawing for explaining an example of a memory device.

Referring to FIG. 11, the memory device 100 may include at least one of a memory cell array 110A, the control logic 120, a page buffer unit 140, a voltage generator 150, and a row decoder 160.

The memory cell array 110A may include a plurality of memory blocks (BLK1 to BLKz). Each of the plurality of memory blocks (BLK1 to BLKz) may include a plurality of strings, and each of the plurality of strings may include a plurality of memory cells and a plurality of selection transistors. The memory cell array 110A may be connected to the page buffer unit 140 via a bitline BL. The memory cell array 110A may be connected to the row decoder 160 via a word line WL, a string selection line SSL, and a ground selection line GSL.

The control logic 120 may control the overall operation of various operations within the memory device 100. The control logic 120 may output various control signals in response to a command CMD and an address ADDR received from the memory controller 200. For example, the control logic 120 may output a voltage control signal to perform an operation according to the command CMD, a block address, a row address, and a column address corresponding to the address ADDR.

The page buffer unit 140 may include a plurality of page buffers (PB1 to PBn). Each of the plurality of page buffers (PB1 to PBn) may be connected to a string through the corresponding bitline BL. The page buffer unit 140 may select at least one bitline among the bitlines BL in response to a column address. The page buffer unit 140 may operate as a write driver or a sense amplifier, depending on its operation. For example, during a program operation, the page buffer unit 140 may change or maintain the threshold voltage of a memory cell by applying a program allowance voltage or a program inhibit voltage to a selected bitline. During the read operation, the page buffer 140 may identify current through the selected bitline and identify the threshold voltage state of the corresponding memory cell.

The voltage generator 150 may generate various types of voltages for performing program operations, read operations, etc. based on voltage control signals. For example, the voltage generator 150 may generate the voltage, the program pass voltage, the program verification voltage, the verification pass voltage, the read voltage, the read pass voltage, etc. to be applied to word lines connected to each page.

The row decoder 160 may select at least one of a plurality of word lines and a plurality of selection lines in response to a row address. The row decoder 160 may deliver various voltages supplied from the voltage generator 150 to selected lines.

A device according to the above described example implementations may include a processor, a memory for storing and executing program data, permanent storage such as disk drives, communication ports to communicate with external devices and user interface devices such as touch panels, keys and buttons. Methods implemented as software modules or algorithms are computer readable codes or program instructions executable on the processor, and may be stored on a computer-readable recording medium. Here, the computer-readable recording medium includes a magnetic storage medium (for example, a read-only memory (ROM), a random-access memory (RAM), a floppy disk and a hard disk) and an optically readable medium (for example, a CD-ROM, a digital versatile disc (DVD)). The computer-readable recording medium may be distributed among network-connected computer systems, so that a computer-readable code may be stored and executed in a distributed manner. The medium may be readable by a computer, stored in a memory, and executed on a processor.

The example implementations may be represented by functional block elements and various processing steps. The functional blocks may be implemented in any number of hardware and/or software configurations that perform specific functions. For example, some implementations may adopt integrated circuit configurations, such as memory, processing, logic and/or look-up table, that may execute various functions by the control of one or more microprocessors or other control devices. Similar to that elements may be implemented as software programming or software elements, the example implementations may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example implementations may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above-described example implementations are merely examples, and other implementations may be implemented within the scope of the claims to be described later.

What is claimed is:

1. A method of operating a memory device comprising a plurality of memory blocks, each memory block of the plurality of memory blocks comprising a plurality of pages, the method comprising:
receiving a read command and an address for controlling a read operation;
identifying that a selected memory block among the plurality of memory blocks is an open block, the selected memory block corresponding to the address; and
based on the selected memory block being identified as the open block, controlling a read pass voltage applied to at least one unselected page of a plurality of unselected pages among a plurality of pages included in the selected memory block, the at least one unselected page being different from a selected page corresponding to the address.

2. The method of claim 1, comprising performing a read operation, the read operation comprising:
applying a first read pass voltage to a programmed page among the plurality of unselected pages;
applying a second read pass voltage to an unprogrammed page among the plurality of unselected pages; and
applying a read voltage to the selected page.

3. The method of claim 2, wherein controlling the read pass voltage comprises controlling a second target level of the second read pass voltage to be smaller than a first target level of the first read pass voltage.

4. The method of claim 2, wherein controlling the read pass voltage comprises controlling a first slope in which a level of the second read pass voltage increases to be smaller than a second slope in which a level of the first read pass voltage increases.

5. The method of claim 2, wherein controlling the read pass voltage comprises controlling a first time taken for a level of the second read pass voltage to reach a second target level to be smaller than a second time taken for a level of the first read pass voltage to reach a first target level.

6. The method of claim 1, comprising:
before receiving the read command and the address, receiving a program command and a previous address to control a program operation; and
performing the program operation on a memory block among the plurality of memory blocks, the memory block corresponding to the previous address,
wherein receiving the read command and the address comprises receiving the read command and the address based on the program operation being incomplete.

7. The method of claim 6, comprising: based on the memory block and the selected memory block being identical,
identifying the selected memory block as the open block; and
maintaining a voltage applied during the program operation, and performing the read operation based on applying the read pass voltage to the at least one unselected page and applying a read voltage to the selected page.

8. The method of claim 6, wherein the program operation comprises:
a program pulse operation in which a program voltage is applied to a selected page of the memory block and a program pass voltage is applied to an unselected page of the memory block; and
a program verification operation in which a program verification voltage is applied to the selected page of the memory block and a verification pass voltage is applied to the at least one unselected page of the memory block; and
wherein the method comprises based on the read operation being complete, resuming a suspended operation during the program pulse operation or the program verification operation.

9. The method of claim 6, wherein receiving the read command and the address comprises:
receiving a suspend command based on the program operation being in progress;
suspending the program operation according to the suspend command; and
receiving the read command and the address based on the program operation being suspended.

10. The method of claim 6, wherein receiving the read command and the address comprises:
receiving the read command and the address based on the program operation being in progress; and
suspending the program operation according to the read command.

11. The method of claim 1, comprising:
receiving a program command and a previous address for controlling a program operation prior to receiving the read command and the address; and
performing the program operation on a memory block among the plurality of memory blocks, the memory block corresponding to the previous address,
wherein receiving the read command and the address comprises receiving the read command and the address based on the program operation being completed.

12. A memory device comprising:
a plurality of memory blocks, each memory block of the plurality of memory blocks comprising a plurality of pages; and
a control logic configured to:
based on receiving a read command and an address configured to control a read operation, identify that a selected memory block among the plurality of memory blocks is an open block, the selected memory block corresponding to the address, and
based on the selected memory block being identified as the open block, control a read pass voltage applied to at least one unselected page of a plurality of unselected pages among a plurality of pages included in the selected memory block, the at least one unselected page being different from a selected page corresponding to the address.

13. The memory device of claim 12, wherein the at least one unselected page comprises a programmed page and an unprogrammed page, and
wherein the control logic is configured to control a second target level of a second read pass voltage applied to the unprogrammed page to be smaller than a first target level of a first read pass voltage applied to the programmed page.

14. The memory device of claim 13, comprising:
a resistor configured to store page information for a last programmed page of the selected memory block,
wherein the control logic is configured to identify, according to the page information, a page next to the last programmed page among the plurality of pages included in the selected memory block as the unprogrammed page.

15. The memory device of claim 12, wherein the at least one unselected page comprises an unprogrammed page, and
wherein the control logic is configured to control a second target level of a second read pass voltage applied to the unprogrammed page to be smaller than a first target level of a first read pass voltage set to be applied to an unselected page of a close block including a programmed page during the read operation for the close block.

16. The memory device of claim 12, wherein the control logic is configured to control a second target level of a second read voltage applied to the selected page of the selected memory block to be larger than a first target level of a first read voltage set to be applied to the selected page of a close block during the read operation for the close block.

17. The memory device of claim 12, wherein the control logic is configured to:
based on receiving a program command and a block address configure to control a program operation, perform the program operation for a memory block among the plurality of memory blocks, the memory block corresponding to the block address,
based on receiving the read command and the address and the program operation being performed, suspend the program operation, and
based on the memory block corresponding to the block address and the selected memory block corresponding to the address being identical, identify the selected memory block as the open block.

18. The memory device of claim 17, wherein the control logic is configured to, based on the memory block and the selected memory block being identical, without discharging a voltage applied during the program operation, apply a read voltage to the selected page and apply a read pass voltage to the at least one unselected page.

19. The memory device of claim 17, comprising:
a resistor configured to store a block address of a previously performed program operation.

20. The memory device of claim 12, wherein the control logic is configured to:
based on receiving a suspend command or the read command and a program operation being performed prior to receiving the read command, suspend the program operation, and
based on the read operation for the selected page of the selected memory block being completed, resume the program operation for the selected memory block.
